(19) United States
(12) Patent Application Publication
(10) Pub. No.: US 2011/0126890 A1
(43) Pub. Date: Jun. 2, 2011

(54) TEXTURED SUPERSTRATES FOR PHOTOVOLTAICS

(76) Inventors: Nicholas Francis Borrelli, Elmira, NY (US); Douglas Warren Hall, Cayucos, CA (US); Glenn Eric Kohnke, Corning, NY (US); Sasha Marjanovic, Painted Post, NY (US)

(21) Appl. No.: 12/955,126

(22) Filed: Nov. 29, 2010

Related U.S. Application Data
(60) Provisional application No. 61/264,929, filed on Nov. 30, 2009.

(51) Int. Cl. H01L 31/0232; H01L 31/06; G02B 5/02; C03C 15/02; B24B 1/00

(52) U.S. Cl. 136/255; 136/256; 359/599; 216/24; 451/41; 451/37; 257/E31.127

(57) ABSTRACT

Textured superstrates for photovoltaic cells, for example, silicon tandem photovoltaic cells with light scattering properties which are sufficient for light trapping independent of wavelength are described herein. Features of a textured surface of a superstrate, via the method(s) used to make the textured superstrate, can be tailored to provide the desired light scattering/trapping properties. The method includes grinding and lapping or grinding, lapping, and etching of a glass superstrate.

This application claims the benefit of priority to U.S. Provisional Application No. 61/264,929 filed on Nov. 30, 2009.

### BACKGROUND

1. Field

Embodiments relate generally to photovoltaic cells, and more particularly to light scattering textured superstrates and methods of making light scattering textured superstrates for, for example, silicon based photovoltaic cells.

2. Technical Background

One important property of a solar cell of any construction is the efficiency; that is the amount of power per unit area developed under standard solar illumination. It is this property that determines the ultimate cost per watt. The theoretical efficiency of a dual (or tandem) structure, having amorphous and microcrystalline silicon, is considered to be superior to cells based on amorphous or microcrystalline silicon alone. The advantage of a tandem structure utilizing both amorphous and microcrystalline silicon is that it is designed to enhance the capture of more of the solar spectrum by the utilization of the combination of both amorphous and microcrystalline silicon. The amorphous silicon portion of the cell absorbs the higher energy region of the solar spectrum, whereas the microcrystalline portion absorbs in the lower energy region.

A typical tandem cell incorporating both amorphous and microcrystalline silicon typically has a substrate having a transparent electrode deposited thereon, a top cell of amorphous silicon, a bottom cell of microcrystalline silicon, and a back contact or counter electrode. Light is typically incident from the side of the deposition substrate such that the substrate becomes a superstrate in the cell configuration.

The practical thickness of the amorphous silicon layer is limited by the Staebler-Wronski effect which reduces the carrier collection with increasing thickness of the amorphous silicon layer. The thickness is limited to only about 300 nanometers (nm), so the absorption of light in this layer needs to be maximized. One such method of maximizing the absorption of light in the amorphous silicon layer is to provide scattering at the interfaces of the layers of the cell, in particular, at the transparent conductive oxide (TCO)/amorphous silicon interface.

As discussed above the major challenge in this type of thin-film solar cell device is to increase the efficiency. In almost all cases because of the limitation on the active film thickness, and therefore the absorption, the major thrust is to find ways to increase the light capture by extending the light path. The typical approach is to provide texture to the TCO film. Many conventional silicon photovoltaic cells use textured TCO films, for example, Asahi-U films produced by Asahi Glass Company.

Another TCO scattering surface known in the art has been fabricated in ZnO with the surface morphology, total transmission and diffuse transmission which is comparable to that of Asahi-u.

Another scattering TCO known in the art is that used by Applied Materials (AMAT) developed by Forschungszentrum Jülich.

Asahi has shown still another type of texture in a TCO film, Asahi HU. Asahi HU has wavelength independent scattering through the visible and near IR.

Disadvantages with textured TCO technology can include one or more of the following: 1) texture roughness degrades the quality of the deposited silicon and creates electrical shorts such that the overall performance of the solar cell is degraded; 2) texture optimization is limited both by the textures available from the deposition or etching process and the decrease in transmission associated with a thicker TCO layer; and 3) plasma treatment or wet etching to create texture adds cost in the case of ZnO.

Another approach to the light-trapping needs for thin film silicon solar cells is texturing of the substrate beneath the TCO and/or the silicon prior to silicon nitride deposition, rather than texture a deposited film. In some conventional thin film silicon solar cells, vias are used instead of a TCO to make contacts at the bottom of the Si that is in contact with the substrate. The texturing in some conventional thin film silicon solar cells consist of SiO₂ particles in a binder matrix deposited on a planar glass substrate. This type of texturing is typically done using a sol-gel type process where the particles are suspended in liquid, the substrate is drawn through the liquid, and subsequently sintered. The beads remain spherical in shape and are held in place by the sintered gel.

Many additional methods have been explored for creating a textured surface prior to TCO deposition. These methods include sandblasting, polystyrene microsphere deposition and etching, and chemical etching. These methods related to textured surfaces can be limited in terms of the types of surface textures that can be created.

Light trapping is also beneficial for bulk crystalline Si solar cells having a Si thickness less than about 100 microns. At this thickness, there is insufficient thickness to effectively absorb all the solar radiation in a single or double pass (with a reflecting back contact). Therefore, cover glasses with large scale geometric structures have been developed to enhance the light trapping. For example, an EVA (ethyl-vinyl acetate) encapsulant material is located between the cover glass and the silicon. An example of such cover glasses are the Albarino® family of products from Saint-Gobain Glass. A rolling process is typically used to form this large-scale structure.

Disadvantages with the textured glass superstrate approach can include one or more of the following: 1) sol-gel chemistry and associated processing is required to provide binding of glass microspheres to the substrate; 2) the process creates textured surfaces on both sides of the glass substrate; 3) additional costs associated with silica microspheres and sol-gel materials; and 4) problems of film adhesion and/or creation of cracks in the silicon film.

It would be advantageous to have textured superstrates for photovoltaic cells, for example, silicon tandem photovoltaic cells with light scattering properties which are sufficient for light trapping independent of wavelength. It would also be advantageous to be able to tailor features of a textured surface of a superstrate, via the method(s) used to make the textured superstrate, to provide the desired light scattering/trapping properties.

### SUMMARY

Textured superstrates and methods of making textured superstrates, as described herein, address one or more of the above-mentioned disadvantages of conventional textured superstrates and methods of making textured superstrates useful for photovoltaic applications, for example, silicon tandem photovoltaic cells.

One embodiment is a method of making a light scattering textured superstrate, the method comprises providing a glass sheet, and grinding and lapping a surface of the glass sheet to form features on the surface of the glass sheet to form the light scattering textured superstrate.

Another embodiment is a light scattering textured superstrate comprising: a glass sheet having a textured surface having features, wherein the textured surface has an RMS roughness in the range of from 100 nm to 1.5 microns and a correlation length in the range of from 500 nm to 2 microns.

Another embodiment is a photovoltaic device comprising the light scattering textured superstrate made by the described methods.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is a plot of total and diffuse transmittance of the exemplary textured glass surfaces.

FIGS. 2A and 2B are scanning electron microscope (SEM) images of a textured glass surface made according to exemplary methods and coated with a TCO.

FIG. 3 is a graph of the angular scattering measured at a wavelength of 633 nm for exemplary light scattering textured superstrates.

FIG. 4 is a plot of the bidirectional transmittance distribution function (BTDF) for an exemplary textured glass superstrate ground, lapped, then etched for 30 minutes.

FIGS. 5A, 5B, 6A and 6B are SEM images of a textured glass surface made according to exemplary methods.

FIGS. 7A and 7B are SEM images of a transparent conductive oxide coated textured glass superstrate made according to exemplary methods.

FIG. 8 is a graph showing haze for glass superstrates having textured surfaces, for example, low (50-250 nm), medium (around 250-500 nm) and high (500 nm-1 micron) made by grinding and lapping and etching.

FIG. 9 is a graph showing total and diffuse transmittance of two different types of glasses with similar surface roughness made by grinding and lapping only.

FIGS. 10, 11, and 12 are graphs showing BTDFs for exemplary ground, lapped, and etched glass superstrates.

FIGS. 13A and 13B are graphs showing total and diffuse transmittance of etched and unetched exemplary light scattering textured glass superstrates, respectively.

FIGS. 14 and 15 are graphs showing ccBTDF of unetched and etched display glass EagleXG™, respectively, having high surface roughness (˜0.5 micron).

FIGS. 16A, 16B, 16C, 16D, and 16E are atomic force microscopy (AFM) images of exemplary textured superstrates made according to the disclosed methods.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “volumetric scattering” can be defined as the effect on paths of light created by inhomogeneities in the refractive index of the materials that the light travels through.

As used herein, the term “surface scattering” can be defined as the effect on paths of light created by interface roughness between layers in a photovoltaic cell.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

It would be advantageous to produce a surface texture on a glass superstrate which provides a scattering behavior that allows more efficient capture of the incident sunlight by the active silicon layers in, for example, a silicon tandem photovoltaic device.

One embodiment is a light scattering textured superstrate comprising: a glass sheet having a textured surface having features, wherein the textured surface has an RMS roughness in the range of from 100 nm to 1.5 microns and a correlation length in the range of from 500 nm to 2 microns.

In another embodiment, the light scattering textured superstrate comprises: a glass sheet having a textured surface having features, wherein the textured surface has an RMS roughness in the range of from 500 nm to 1.25 microns and a correlation length in the range of from 750 nm to 1.6 microns.

In another embodiment, the light scattering textured superstrate comprises: a glass sheet having a textured surface having features, wherein the textured surface has an RMS roughness in the range of from 700 nm to 1 micron and a correlation length in the range of from 800 nm to 1.2 microns.

One embodiment is a photovoltaic device comprising the light scattering textured superstrates as described by the embodiments herein. In the glass sheet configuration, the surface with the largest surface area is textured. In one embodiment, the glass sheet is substantially flat. In one embodiment, the flat glass sheet has two opposing flat surfaces. In the photovoltaic device, in one embodiment, one surface of the glass sheet is textured; the textured glass sheet is in the superstrate configuration and is incident to light and the textured surface is on the opposite side of the glass as the incoming light. In one embodiment, the opposite surface is also textured.

The parameters that can be used to characterize the light scattering behavior of the light scattering textured superstrates described herein are total 180 degree forward transmission; total diffuse transmission which is the total forward scattering excluding the portion −2.5<theta<2.5 degrees (ASTM standard definition); total and diffuse reflection versus wavelength; angular scattering as a function of wavelength; surface morphology; root mean square (RMS) roughness and spatial frequency make up (correlation length from power spectrum); atomic force microscope (AFM) images; and scanning electron microscope (SEM) images. Lc (correlation length) is the correlation function—a measure of the order in a system, as characterized by a mathematical correlation function, and describes how microscopic variables at different positions are correlated.

Ray tracing models were used to simulate the efficiency ((Maximum Achievable Current Density (MACD)) of silicon tandem cells to define the characteristics of optimized substrate textured surfaces. Textured superstrate surfaces consisted of a 25 microns×25 microns area of an AFM scan that was scaled as follows: x,y dimension—2/3, 1, 3/2, surface height—2/3, 1, 3/2. A total of 9 simulations were done. Subsequent interfaces were derived using the thin-film conformal growth (TFCG) model. Table 1 shows ray tracing model results.

TABLE 1

| | | Relative Surface | | |
|---|---|---|---|---|
| | | Roughness | | |
| | | ⅔ | 1 | 3/2 |
| Relative | ⅔ | 5.5% | 8.5% | 10.6% |
| Correlation | 1 | 1.9% | 6.0% | 8.1% |
| Length | 3/2 | −0.5% | 1.3% | 3.3% |

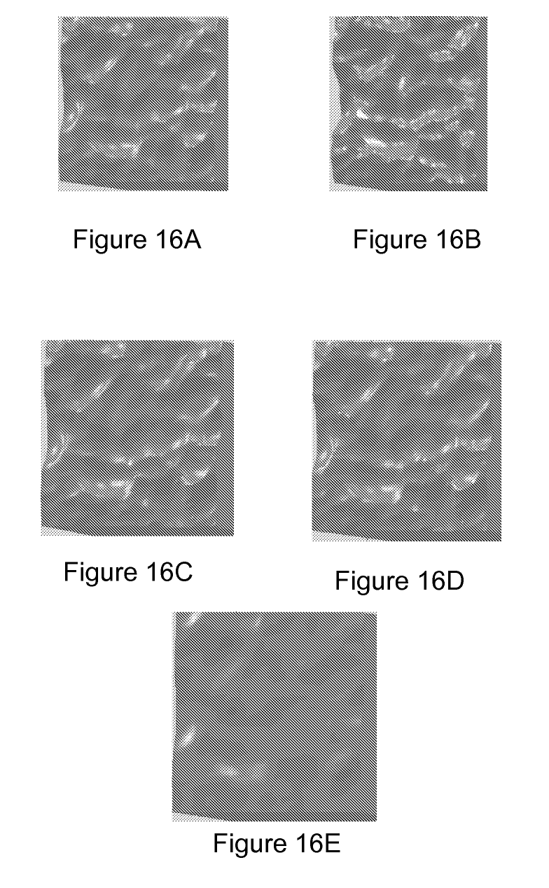

FIGS. 16A, 16B, 16C, 16D, and 16E are AFM images of exemplary light scattering textured superstrates made according to the disclosed methods and having the properties listed in Table 1. FIG. 16A shows a top down view of the surface of a textured superstrate having an Lc of 2/3 and a relative surface roughness of 2/3. FIG. 16B shows a top down view of the surface of a textured superstrate having an Lc of 3/2 and a relative surface roughness of 2/3. FIG. 16C shows a top down view of the surface of a textured superstrate having an Lc of 1 and a relative surface roughness of 1. FIG. 16D shows a top down view of the surface of a textured superstrate having an Lc of 3/2 and a relative surface roughness of 3/2. FIG. 16E shows a top down view of the surface of a textured superstrate having an Lc of 2/3 and a relative surface roughness of 3/2.

The surface of a textured superstrate having an Lc of 1 and a relative surface roughness of 1 simulation shows an enhancement of 6%. This higher value compared with previous result is probably caused by improved (less “rounding”) surface fitting. Increasing roughness and/or decreasing correlation length improves performance. Increasing the roughness alone or decreasing the correlation length alone increases performance. Increasing roughness and decreasing correlation length together increases performance of most. These limits cannot be extended indefinitely. In general, electrical performance limits roughness. TFCG may limit benefit from reduction in correlation length. The ‘extra’ silicon deposited (via conformal growth) does not account for the majority of the enhanced performance.

According to some embodiments, the light scattering textured superstrate has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the glass sheet can have a thickness of any numerical value including decimal places in the range of from 0.1 mm up to and including 4.0 mm.

In one embodiment, the surface of the light scattering textured superstrate has an RMS roughness in the range of from 100 nm to 1.5 microns and a correlation length in the range of from 500 nm to 2 microns. In another embodiment, the surface of the light scattering textured superstrate has an RMS roughness in the range of from 500 nm to 1.25 microns and a correlation length in the range of from 750 nm to 1.6 microns. In another embodiment, the surface of the light scattering textured superstrate has an RMS roughness in the range of from 700 nm to 1 micron and a correlation length in the range of from 800 nm to 1.2 microns.

One embodiment is a method of making a light scattering textured superstrate, the method comprises providing a glass sheet, and grinding and lapping a surface of the glass sheet to form features on the surface of the glass sheet to form the light scattering textured superstrate.

Parameters can be set forth for the grinding and lapping process that can ultimately determine how the features of the textured superstrate develop. The parameters are, for example, grit composition, grit size; grit deposition, for example, pad, slurry; lapping technique, or glass composition as it relates to its hardness.

In one embodiment, the method comprises grinding and lapping with a grinding media slurry comprising abrasive particles and water, for example, deionized water. The abrasive particles can have average diameters of greater than 0 to 15 microns, for example, 1 to 10 microns, for example, 1 to 5 microns. In one embodiment, the abrasive particles comprise alumina.

In one embodiment, the grinding and lapping comprises feeding a lapping pad with the grinding media. Feeding the grinding media, according to one embodiment, comprises dripping the grinding media drop wise onto the lapping pad.

According to one embodiment, the lapping pad is a plate comprising a material selected from stainless steel, glass, copper, or combinations thereof. The lapping plate can have a textured surface or a patterned surface, for example, a grooved glass plate.

According to one embodiment, the grinding and lapping comprises rotating a lapping pad underneath a surface of the glass sheet, wherein the grinding slurry is in contact with the surface of the glass sheet. In one embodiment, the glass sheet is stationary. The rotation speed can be adjusted to optimize the final textured surface of the superstrate. If the rotation is too fast, for example, the glass sheet may become scratched as opposed to ground.

The method further comprises, in one embodiment, etching the features on the ground and lapped surface with an acid. Etching conditions, for example, etch solution composition and etch time are parameters which can be changed to further tailor the features of the textured surface.

In one embodiment, the etching comprises exposing the ground and lapped surface to an acid solution comprising hydrofluoric acid, hydrochloric acid, water, or a combination thereof. The acid can comprise hydrofluoric acid, hydrochloric acid, and water at a ratio of, for example, 1 to 1 to 20, respectively or, for example, 2 to 2 to 20 or, for example, 5 to 5 to 20. The water can be, for example, deionized water.

In one embodiment, the grinding, lapping, and etching comprises grinding and lapping the glass sheet with a fine grit followed by a hydrofluoric (HF)/hydrochloric (HCl) solution etching process to provide a controlled smoothing of the surface morphology.

The grinding and lapping, or etching processes allow tailoring of the processes to control the roughness and texture of features on the light scattering superstrate and thus the magnitude of the total and diffuse transmission as well as the angular scattering.

### EXAMPLES

The latter parameters and their influence on surface roughness and light scattering behavior was investigated.

Light scattering glass superstrates having a textured surface having low (50-250 nm), medium (around 250-500 nm) and high (500 nm-1 micron) or very high surface roughness were made according to the methods disclosed herein.

Several different types of glasses were tested, from display quality to ultra high quality and specialty glasses, such as Eagle XG™, HPFS®, soda-lime, specialty glass for CdTe solar cells, etc. Some glasses are more suitable for chemical-mechanical surface polishing, lapping, grinding and etching processes than others. In addition, lower index glasses may offer slightly higher QE due to lower Fresnel reflection from the glass surface.

According to one embodiment, the textured glass surface comprises features having an average diameter in the range of from 100 nanometers to 15 microns, for example, 100 nm to 10 microns, for example, 100 nm to 5 microns. According to one embodiment, the textured glass surface comprises features having an average diameter in the range of from 100 nanometers to 2 microns, for example, from 250 nanometers to 1.5 microns.

According to one embodiment, the textured glass surface comprises features with average diameters greater than 1.5 microns with some features reaching 10 microns or more. Usually one expects scattering to occur only if the scattering feature is on the order of the size of wavelength of light. An example of the very highly textured glass surface is shown in the SEM images in FIGS. 2A and 2B. The light scattering textured glass surface in these examples was coated with a TCO.

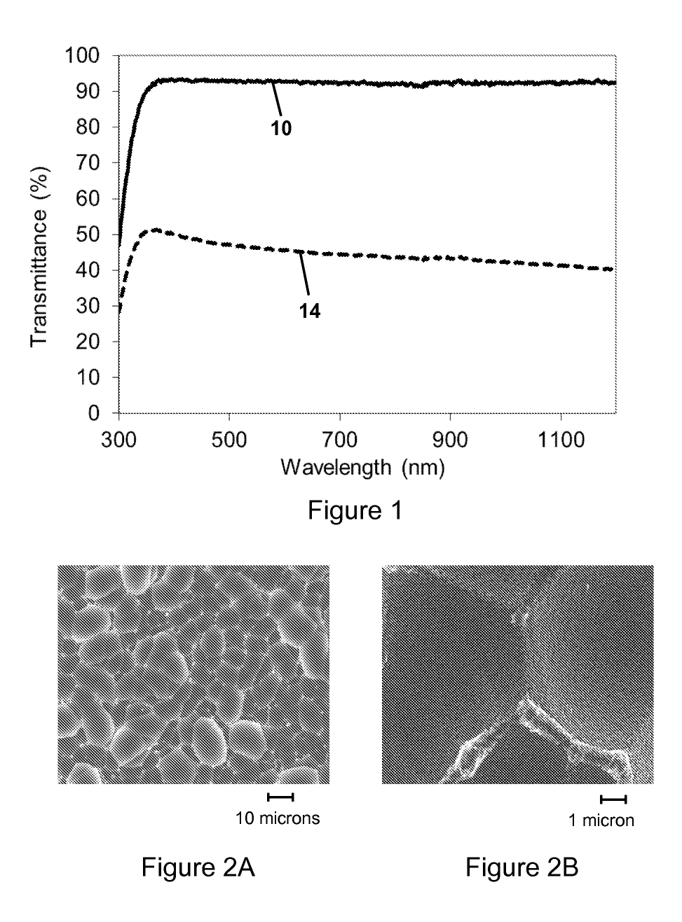

In one embodiment, the light scattering article comprises a glass sheet having a surface with features which scatter light in a controllable manner so as to enhance the light absorption in the subsequent active silicon layer(s). The scattering function provided by the textured glass surface, in this example, a ground and lapped, and etched glass sheet, is essentially independent of wavelength. In addition the total transmission is >80% over the solar spectrum and has haze or a scatter ratio (ratio of the scattered light intensity with angle >2.5 degrees to the total forward intensity) of greater than 85% as shown in FIG. 1. FIG. 1 is a plot of total and diffuse transmittance of the exemplary textured glass surfaces with macro texturing shown in FIGS. 2A and 2B. Line 10 shows total transmittance. Line 14 shows diffuse transmittance.

Grinding media with alumina particles having average diameters in the range of from 0.5 microns to 10 microns, for example, 2, 3, 5, 7, and 9 microns and deionized water were used for grinding and lapping glass sheets. A significant difference in the light scattering behavior of resulting textured glass superstrates among the 5, 7, and 9 grit sizes was not seen.

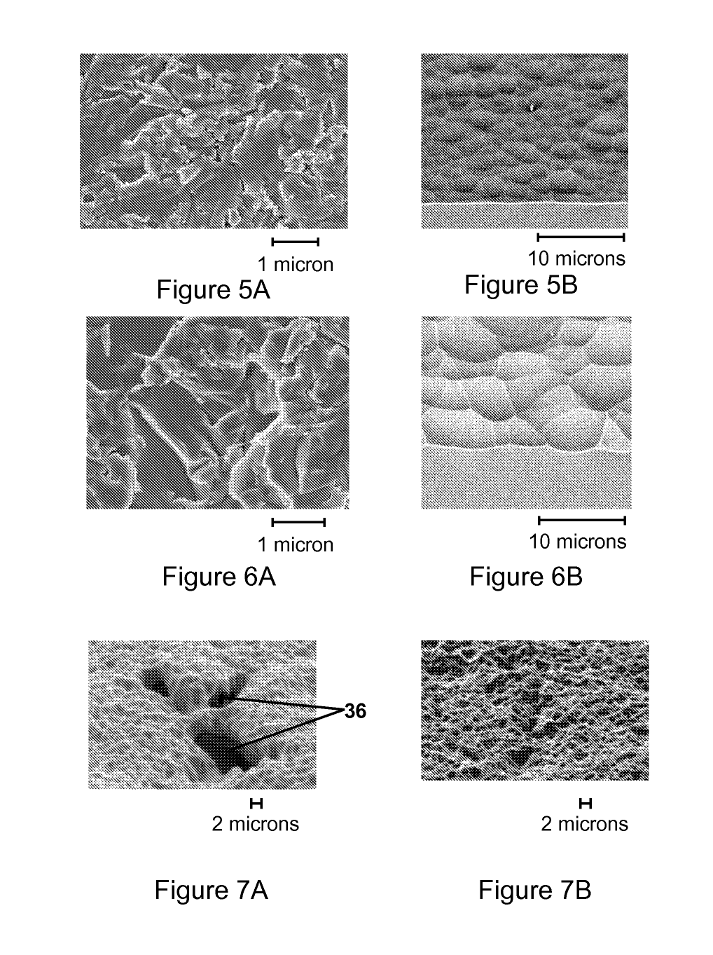

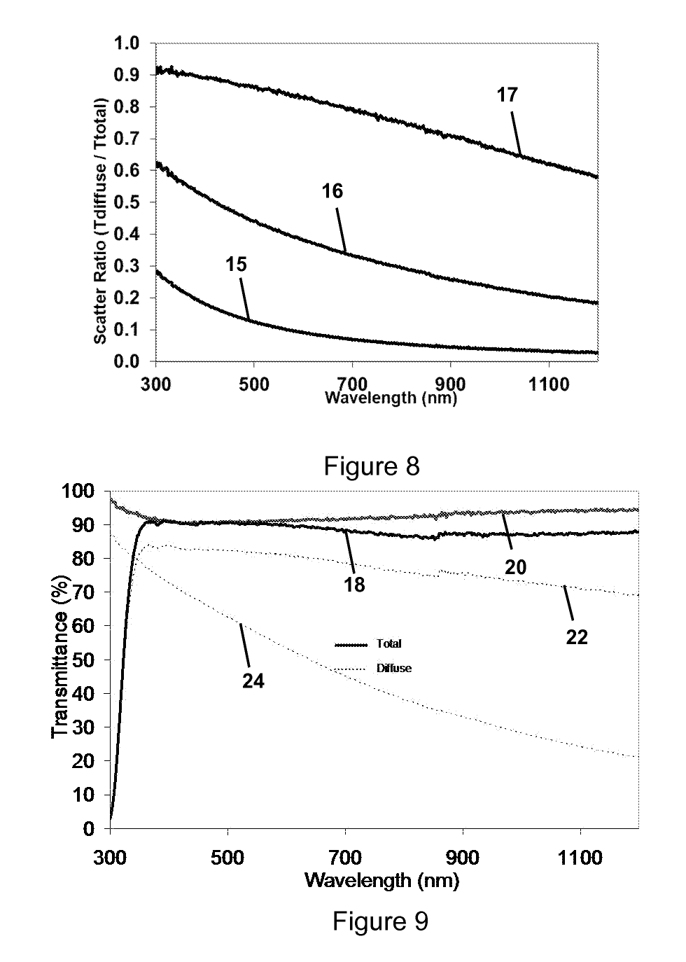

Exemplary unetched textured glass surfaces were made by grinding and lapping with a slurry comprising alumina particles with grit sizes around 2 microns in average diameter and deionized water and using a grooved glass lapping pad. Images of these textured surface are shown in the SEMs in FIGS. 5A and 6A. FIG. 8 is a graph showing haze for glass superstrates having textured surfaces, for example, low (50-250 nm), medium (around 250-500 nm) and high (500 nm-1 micron) roughness made by grinding and lapping and etching shown by lines 15, 16, and 17, respectively. Haze may be described as a scattering ratio of diffuse transmittance over total transmittance. FIG. 9 shows total and diffuse transmittance of two different types of glasses with similar surface roughness made by grinding and lapping only. Total and diffuse transmittance for high purity fused silica is shown by lines 20 and 22 respectively. Total and diffuse transmittance for soda lime is shown by lines 18 and 24 respectively.

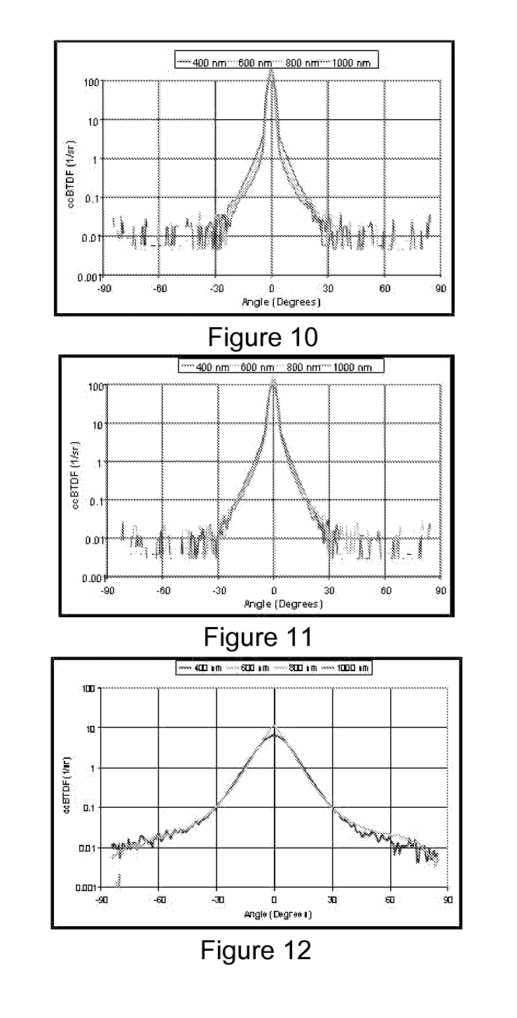

A series of etch times in the 5% HF/HCl solution ranging from 5 minutes to 90 minutes was also tested. FIGS. 10, 11 (5 minute etch), and 12 (11 minute etch) are graphs showing BTDFs for ground, lapped, and etched glass superstrates having textured surfaces, for example, low (50-250 nm), medium (around 250-500 nm) and high (500 nm-1 micron) roughness, respectively. Images of the textured surface shown in the SEMs in FIGS. 5A and 6A and subsequently etched are shown in FIGS. 5B and 6B. The textured surfaces shown in FIGS. 5A and 5B were etched with the 5% HF/HCl solution for 5 minutes and 11 minutes, respectively, and resulted in the textured surfaces shown in FIGS. 5B and 6B. Zygo measurements were taken of exemplary low, medium, and high roughness surfaces. The low roughness surface had a mean rms roughness of 123.4 nm with a standard deviation of 26.5 nm. The medium roughness surface had a mean rms roughness of 449.4 nm with a standard deviation of 63.6 nm. The high roughness surface had a mean rms roughness of 713.1 nm with a standard deviation of 9.3 nm. A total transmission above 85% combined with a high diffuse transmission is desirable. The correlation length of the medium and high roughness exemplary textured surfaces is 750 nm to 2 microns. The morphology and grain size and thus correlation length can be tailored by the methods described herein.

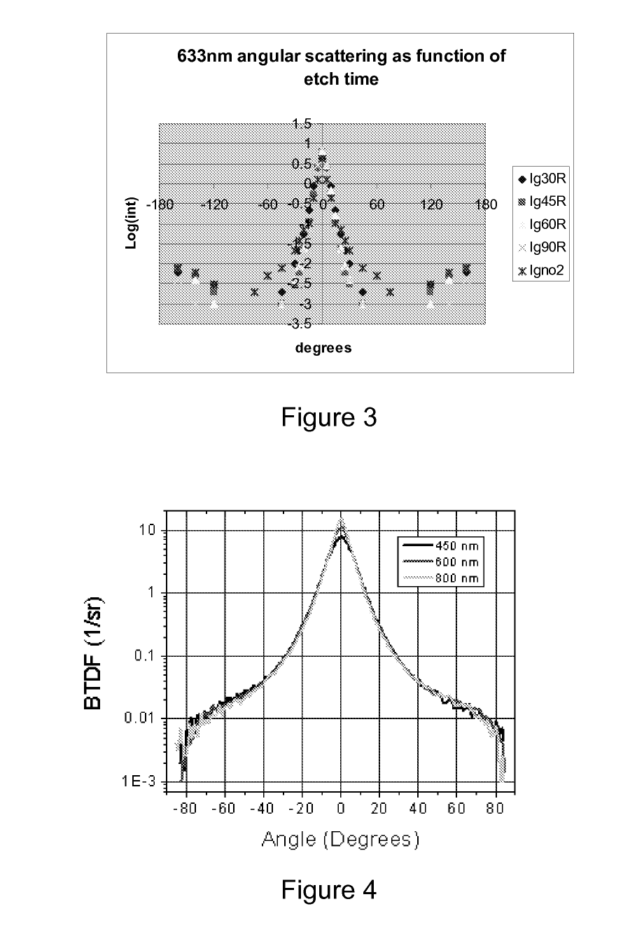

Ground and lapped glass superstrates were etched for 30, 45, 60, and 90 minutes the hydrofluoric (HF)/hydrochloric (HCl)/water solution in a 1/1/20 ratio. The HF and HCl were commercially available chemicals. The transmittance over the full spectrum of light was compared to an unetched ground and lapped glass superstrate. The total transmission was increased with etching and wavelength flattened showing the transmission is independent of wavelength, both behaviors are beneficial. For the 30 minute etch, the diffuse scattering is increased relative to the longer etch times with no loss of total transmission which again is beneficial. For the 15 minute etch a similar result was observed. This shows the role of the etching step in optimizing the transmission and scattering. FIG. 3 is the angular scattering measured at a wavelength of 633 nm for the same set of samples.

The trend of the width of the angular scattering measured at 633 nm is diminished with etch time. The bidirectional transmittance distribution function (BTDF) is shown in FIG. 4 for the exemplary textured glass superstrate etched for 30 minutes. The BTDF data shows the wavelength independence of the textured surface.

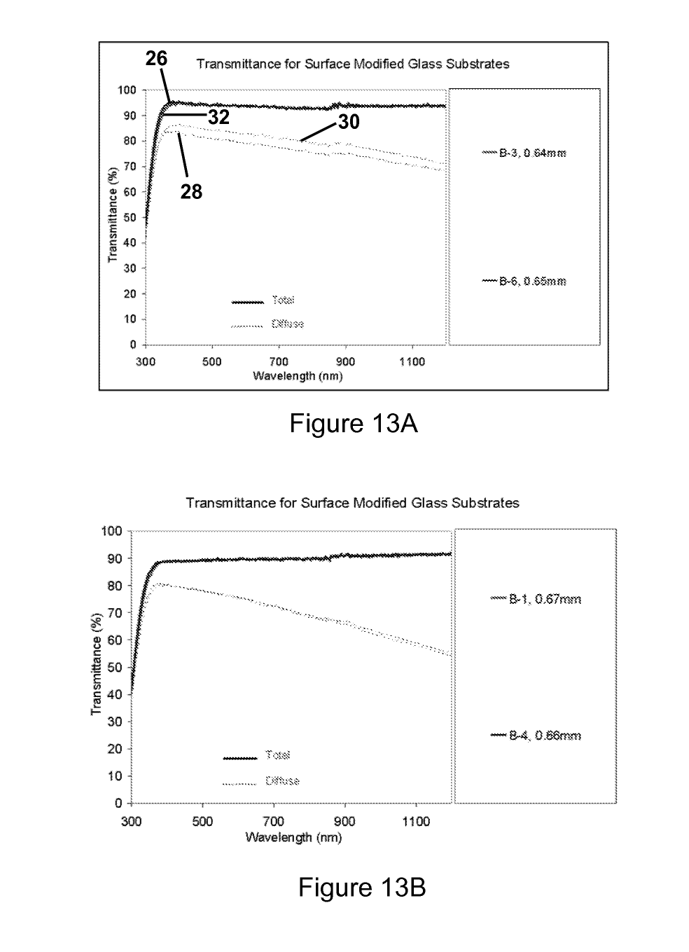

FIGS. 13A and 13B are graphs showing total and diffuse transmittance of etched and unetched, respectively, exemplary light scattering textured glass superstrates. Lines 32 and 30 show total and diffuse transmittance of an exemplary light scattering textured superstrate made by grinding and lapping and etching. Lines 26 and 28 show total and diffuse transmittance of an exemplary light scattering textured superstrate made by grinding and lapping.

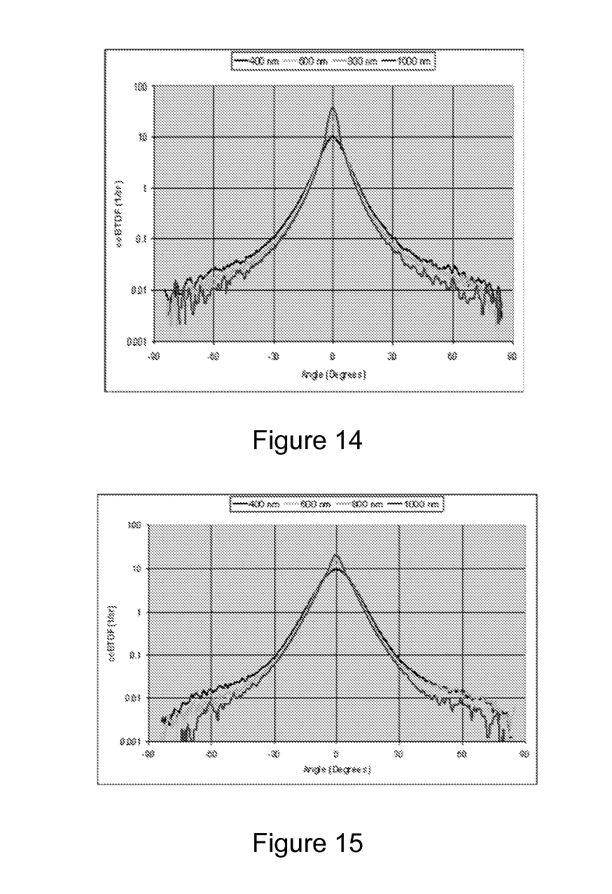

FIGS. 14 and 15 are graphs showing ccBTDF of unetched and etched display glass EagleXG™, respectively, having high surface roughness (˜0.5 micron).

The exact physical connection between the scattering behavior and a particular surface texture defies explanation in simple terms. Surface textures are typically characterized in terms of the RMS roughness and a correlation length.

AFM measurements were taken of the exemplary textured glass surfaces with macro texturing shown in FIGS. 2A and 2B. The finer structure is shown in the higher magnification SEM. The finer texture in the features contributes to the higher spatial frequency component of the scattering. The correlation length of these exemplary textured surfaces is greater than 5 microns.

Another embodiment is a photovoltaic device comprising the light scattering textured superstrate made by the described methods. The photovoltaic device, according to one embodiment, comprises a conductive material adjacent to the superstrate, and an active photovoltaic medium adjacent to the conductive material. The conductive material is a transparent conductive film, in some embodiments. The transparent conductive film comprises a textured surface, in one embodiment. The active photovoltaic medium, according to one embodiment, is in physical contact with the transparent conductive film.

The device, according to one embodiment, further comprises a counter electrode in physical contact with the active photovoltaic medium and located on an opposite surface of the active photovoltaic medium as the conductive material. The active photovoltaic medium can comprise multiple layers. In one embodiment, the active photovoltaic medium comprises amorphous silicon, microcrystalline silicon, or a combination thereof.

Light scattering properties of surface-textured transparent conductive oxide (TCO) substrates have become an important issue in the process of optimization of thin-film solar cell performance. Light trapping effect in a tandem amorphous/microcrystalline silicon (a-Si:H/μc-Si:H) photovoltaic solar cells is very important for providing high quantum efficiency since a μc-Si:H thin film has lower optical absorption coefficient than a-Si:H film. An efficient light trapping not only leads to higher short circuit current (J_{sc}), but also allows thinner intrinsic μc-Si:H and TCO layers, which is particularly important for reducing overall cost of making of such solar cells. It is for these reasons and potentially huge market opportunities that light trapping in a-Si:H/μc-Si:H tandem photovoltaic solar cells attract significant interest.

Light scattering also depends on the morphology of the textured glass surfaces (interfaces). Therefore, the efficient light trapping in these thin-film solar cells is based on scattering of light at rough interfaces, which are introduced into solar cells by using superstrates with textured surface. Traditionally, a-Si:H solar cells in the superstrate configuration have used surface-textured TCO contact layer, typically either ZnO or SnO₂. However, both superstrate and TCO can be surface-textured for maximum light trapping effect. We have developed a chemical-mechanical method for glass surface-texturing that, together with textured TCO, offers high J_{sc} and allows thinner intrinsic μc-Si:H and TCO layers in a-Si:H/μc-Si:H tandem solar cells.

Surface textured glasses as superstrates may improve light-trapping and, therefore, quantum efficiency in thin-film Si-Tandem photovoltaic solar cells. Surface texturing by means of chemical-mechanical processes may cause an increased light scattering from such surfaces, which may cause increased light trapping in Si-Tandem silicon layers. However, there may be limits in the magnitude of the surface roughness that would benefit quantum efficiency. For example, too rough of surfaces may cause significant shunting of a solar cell. FIG. 7A is an SEM image of a transparent conductive oxide coated textured glass superstrate made according to exemplary methods and is an example of rough surface having pinholes 36. These pinholes could cause shunting or delamination of the TCO in a photovoltaic cell. On the other hand, too smooth of surfaces, while still produce some light scattering, may not significantly improve QE efficiency and are very cost inefficient. FIG. 7B is an SEM image of a transparent conductive oxide coated textured glass superstrate made according to exemplary methods and having optimum roughness.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A method of making a light scattering textured superstrate, the method comprising:
providing a glass sheet; and
grinding and lapping a surface of the glass sheet to form features on the surface of the glass sheet to form the light scattering textured superstrate.

2. The method according to claim 1, further comprising etching the features on the ground and lapped surface with an acid.

3. The method according to claim 2, wherein the etching comprises exposing the ground and lapped surface to an acid solution comprising hydrofluoric acid, hydrochloric acid, water, or a combination thereof.

4. The method according to claim 3, wherein the acid comprises hydrofluoric acid, hydrochloric acid, and water at a ratio of 1 to 1 to 20.

5. The method according to claim 1, wherein the grinding and lapping comprises applying a grinding media to a lapping plate, wherein the grinding media contacts the surface of the glass sheet.

6. The method according to claim 5, wherein the lapping pad is a plate comprising a material selected from stainless steel, glass, copper, or combinations thereof.

7. The method according to claim 6, wherein the lapping plate comprises a textured surface.

8. The method according to claim 5, wherein the grinding media comprises alumina particles in water.

9. The method according to claim 6, wherein the particles have an average diameter in the range of from greater than 0 to 15 microns.

10. The method according to claim 1, wherein the features have an average diameter of from 100 nanometers to 15 microns.

11. The method according to claim 1, wherein the surface of the light scattering textured superstrate has an RMS roughness in the range of from 100 nm to 1.5 microns and a correlation length in the range of from 500 nm to 2 microns.

12. The method according to claim 1, wherein the surface of the light scattering textured superstrate has an RMS roughness in the range of from 500 nm to 1.25 microns and a correlation length in the range of from 750 nm to 1.6 microns.

13. The method according to claim 1, wherein the surface of the light scattering textured superstrate has an RMS roughness in the range of from 700 nm to 1 micron and a correlation length in the range of from 800 nm to 1.2 microns.

14. A light scattering textured superstrate comprising: a glass sheet having a textured surface having features, wherein the textured surface has an RMS roughness in the range of from 100 nm to 1.5 microns and a correlation length in the range of from 500 nm to 2 microns.

15. A light scattering textured superstrate comprising: a glass sheet having a textured surface having features, wherein the textured surface has an RMS roughness in the range of from 500 nm to 1.25 microns and a correlation length in the range of from 750 nm to 1.6 microns.

16. A light scattering textured superstrate comprising: a glass sheet having a textured surface having features, wherein the textured surface has an RMS roughness in the range of from 700 nm to 1 micron and a correlation length in the range of from 800 nm to 1.2 microns.

17. The light scattering textured superstrate according to claim 14, wherein the glass sheet has a thickness of 4.0 mm or less.

18. A photovoltaic device comprising the light scattering superstrate made according to claim 14.

19. A photovoltaic device comprising the light scattering superstrate made according to claim 1.

20. The photovoltaic device according to claim 19 comprising:
a conductive material adjacent to the superstrate; and
an active photovoltaic medium adjacent to the conductive material.

21. The device according to claim 20, wherein the conductive material is a transparent conductive film.

22. The device according to claim 21, wherein the transparent conductive film comprises a textured surface.

23. The device according to claim 21, wherein the active photovoltaic medium is in physical contact with the transparent conductive film.

24. The device according to claim 21, further comprising a counter electrode in physical contact with the active photovoltaic medium and located on an opposite surface of the active photovoltaic medium as the conductive material.

25. The device according to claim 21, wherein the active photovoltaic medium comprises multiple layers.

26. The device according to claim 20, wherein the active photovoltaic medium comprises amorphous silicon, microcrystalline silicon, or a combination thereof.
